(19) United States
(12) Patent Application Publication
(10) Pub. No.: US 2024/0055532 A1
(43) Pub. Date: Feb. 15, 2024

(54) DISPLAY APPARATUS

(71) Applicant: LG Display Co., Ltd., Seoul (KR)

(72) Inventors: Sunyoung CHOI, Seoul (KR); Sangsoon NOH, Goyang-si (KR); Dongchae SHIN, Goyang-si (KR)

(21) Appl. No.: 18/362,822

(22) Filed: Jul. 31, 2023

(30) Foreign Application Priority Data
Aug. 11, 2022 (KR) 10-2022-0100755

(51) Int. Cl. H01L 29/786; H01L 29/417

(52) U.S. Cl. CPC H01L 29/7869; H01L 29/78696; H01L 29/41733

(57) ABSTRACT

A display apparatus includes an oxide semiconductor layer on a substrate; a gate insulating film on the oxide semiconductor layer; a gate electrode on the gate insulating film; a first interlayer insulating film on the gate insulating film and the gate electrode; a second interlayer insulating film on the first interlayer insulating film; a source electrode connected to the oxide semiconductor layer; and a drain electrode spaced apart from the source electrode and connected to the oxide semiconductor layer, wherein the oxide semiconductor layer includes: a channel area overlapping the gate electrode; a source area connected to the source electrode; a drain area connected to the drain electrode; an intermediate source area between the channel and source areas; and an intermediate drain area between the channel and drain areas, wherein a hydrogen concentration of each of the intermediate source and drain areas is lower than that of each of the source and drain areas.

### CROSS-REFERENCE TO RELATED APPLICATION

This application claims priority from Korean Patent Application No. 10-2022-0100755 filed on Aug. 11, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to a display apparatus. More specifically, the present disclosure relates to a display apparatus including an oxide semiconductor thin-film transistor in which a short channel effect can be reduced.

### Description of Related Art

Various display apparatuses such as a liquid crystal display apparatus (LCD), an organic light-emitting display apparatus (OLED), and a quantum dot display apparatus are being developed.

A thin-film transistor is widely used as a switching element or a driving element in the various display apparatuses. The thin-film transistors may be classified into an amorphous silicon thin-film transistor, a polycrystalline silicon thin-film transistor, and an oxide semiconductor thin-film transistor.

Recently, as large-area models and high-definition models increase in the display apparatuses, the oxide semiconductor thin-film transistor which is advantageous in securing a uniformity in a display panel and has high mobility is widely used in the display apparatus.

### SUMMARY

A sub-pixel of an active matrix type display apparatus is provided with a pixel circuit including a driving thin-film transistor and at least one switching thin-film transistor.

In the display apparatus used in a high-definition model (for example, the display apparatus as used in a mobile phone), a size of a sub-pixel is small such that there is a limit to a size of the thin-film transistor disposed in the sub-pixel.

Therefore, for stable sub-pixel operation, a channel length of the driving thin-film transistor is designed to be relatively larger than that of the switching thin-film transistor. As the channel length of the switching thin-film transistor becomes smaller, it is difficult to obtain stable characteristics of the switching thin-film transistor, due to the short channel effect such as threshold voltage lowering (Vth roll-off), DIBL (drain induced barrier lowering), etc.

Accordingly, the inventors of the present disclosure have invented a novel method of manufacturing an oxide semiconductor thin-film transistor in which the short channel effect can be reduced, and have invented a display apparatus including the oxide semiconductor thin-film transistor manufactured thereby.

A technical purpose according to embodiments of the present disclosure is to provide display apparatuses including an oxide semiconductor thin-film transistor in which a short channel effect can be reduced.

Purposes according to the present disclosure are not limited to the above-mentioned purpose. Other purposes and advantages according to the present disclosure that are not mentioned may be understood based on following descriptions and may be more clearly understood based on embodiments according to the present disclosure. Further, it will be easily understood that the purposes and advantages according to the present disclosure may be realized using means shown in the claims or combinations thereof.

An aspect of the present disclosure provides a display apparatus comprising: a substrate; an oxide semiconductor layer disposed on the substrate; a gate insulating film disposed on the oxide semiconductor layer; a gate electrode disposed on the gate insulating film; a first interlayer insulating film disposed on the gate insulating film and the gate electrode; a second interlayer insulating film disposed on the first interlayer insulating film; a source electrode connected to the oxide semiconductor layer; and a drain electrode spaced apart from the source electrode and connected to the oxide semiconductor layer, wherein the oxide semiconductor layer includes: a channel area overlapping the gate electrode; a source area connected to the source electrode; a drain area connected to the drain electrode; an intermediate source area disposed between the channel area and the source area; and an intermediate drain area disposed between the channel area and the drain area, wherein a hydrogen concentration of each of the intermediate source area and the intermediate drain area is lower than a hydrogen concentration of each of the source area and the drain area.

Another aspect of the present disclosure provides a display apparatus comprising: a substrate; an oxide semiconductor layer disposed on the substrate; a gate insulating film disposed on the oxide semiconductor layer; a gate electrode disposed on the gate insulating film; a silicon oxide film disposed on the gate insulating film and the gate electrode; and a silicon nitride film disposed on the silicon oxide film, wherein the oxide semiconductor layer includes: a source area; a drain area; an intermediate source area having a hydrogen concentration lower than a hydrogen concentration of the source area; and an intermediate drain area having a hydrogen concentration lower than a hydrogen concentration of the drain area.

Details of other embodiments are included in the detailed description and drawings.

According to the aspects of the present disclosure, the oxide semiconductor layer of the thin-film transistor has the intermediate source area and the intermediate drain area respectively disposed between the channel area and the source area and between the channel area and the drain area, and having electrical conductivity or the hydrogen concentrations lower than those of the source area and the drain area, respectively. Thus, the short-channel effect of the thin-film transistor can be reduced or suppressed to secure stable characteristics of the thin-film transistor.

According to the aspects of the present disclosure, the silicon oxide film and the silicon nitride film are sequentially disposed on the gate electrode of the thin-film transistor including the oxide semiconductor layer. In this regard, the silicon oxide film has one portion overlapping the gate electrode, and the other portion non-overlapping the gate electrode, wherein a thickness of the one portion is larger than a thickness of the other portion. Alternatively, the silicon nitride film has one portion overlapping the gate electrode, and the other portion non-overlapping the gate electrode, wherein a thickness of the one portion is smaller than a thickness of the other portion. Alternatively, the silicon nitride film has an opening therein overlapping the gate electrode so as to partially expose the silicon oxide film. Thus, without a separate ion implantation process, the channel area, the source area, the drain area, the intermediate source area and the intermediate drain area having electrical conductivity lower than those of the source area and the drain area may be formed in the oxide semiconductor layer. Thus, the short-channel effect of the thin-film transistor can be reduced or suppressed to secure stable characteristics of the thin-film transistor.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a plan view illustrating a display apparatus according to an embodiment of the present disclosure.

FIG. 2 is an equivalent circuit diagram illustrating one sub-pixel in a display apparatus according to an embodiment of the present disclosure.

FIG. 3 is a schematic cross-sectional view showing one sub-pixel in a display apparatus according to an embodiment of the present disclosure.

FIG. 4 is a cross-sectional view showing a partial area including the switching thin-film transistor of FIG. 3.

FIGS. 5 to 7 are cross-sectional views respectively showing modified structures of the partial area including the switching thin-film transistor of FIG. 3 according to embodiments of the present disclosure.

FIG. 8A to FIG. 8C are cross-sectional views showing a manufacturing process of a switching thin-film transistor as shown in FIG. 4.

FIG. 9A to FIG. 9D are cross-sectional views showing a manufacturing process of a switching thin-film transistor as shown in FIG. 5.

FIG. 10A to FIG. 10D are cross-sectional views showing a manufacturing process of a switching thin-film transistor as shown in FIG. 6.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc., disclosed in the drawings for describing the embodiments of the present disclosure are examples, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which the embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display apparatus according to an embodiment of the present disclosure will be described in detail with reference to the accompanying drawings.

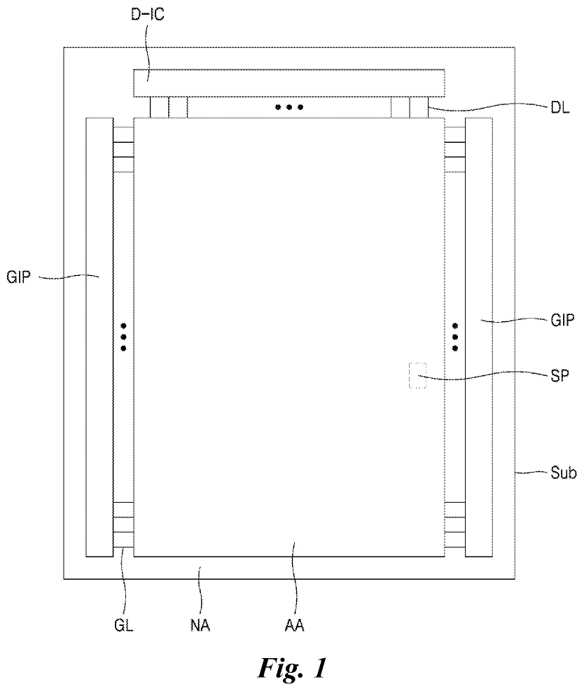

FIG. 1 is a plan view illustrating a display apparatus according to an embodiment of the present disclosure.

The display apparatus includes a substrate Sub, and a display area AA and a non-display area NA around the display area AA disposed on the substrate. A gate driver GIP is disposed on the substrate Sub and in the non-display area NA. A data driver D-IC is disposed on the substrate Sub and in the non-display area NA.

The display area AA on the substrate Sub is an area where a plurality of sub-pixels SP are arranged and an image is displayed. Each sub-pixel SP may emit, for example, red, green, blue, or white light. However, the present disclosure is not limited thereto. A light-emitting element for displaying an image and a pixel circuit for driving the light-emitting element may be disposed in each sub-pixel SP. The pixel circuit may include a driving thin-film transistor, at least one switching thin-film transistor, and at least one capacitor. The light-emitting element may be, for example, an organic light-emitting diode.

The non-display area NA on the substrate Sub is an area where an image is not displayed, and is an area where drivers for driving a plurality of sub-pixels SP disposed in the display area AA, and various lines are disposed. The gate driver GIP, the data driver D-IC, gate lines GL, and data lines DL may be disposed in the non-display area NA.

The gate driver GIP is controlled according to a plurality of gate control signals supplied from a timing controller, and individually drives the gate lines GL. The data driver D-IC is controlled according to a data control signal supplied from the timing controller, converts digital data supplied from the timing controller into an analog data signal, and supplies the analog data signal to each of the data lines DL. The data driver D-IC may supply a reference voltage to a reference line.

As shown in FIG. 1, the non-display area NA may be an area surrounding an edge of the display area AA. In FIG. 1, the non-display area NA is shown as surrounding a rectangular display area AA. However, the shape of the display area AA and the shape and the position of the non-display area NA adjacent to the display area AA are not limited to an example as shown in FIG. 1. Each of the display area AA and the non-display area NA may have a form suitable for a design of an electronic apparatus on which the display apparatus is mounted. An example of the shape of the display area AA may be pentagonal, hexagonal, circular, elliptical, etc. However, the present disclosure is not limited thereto.

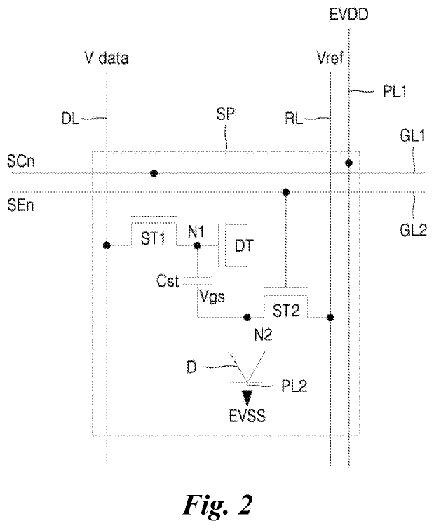

FIG. 2 is an equivalent circuit diagram illustrating one sub-pixel in a display apparatus according to an embodiment of the present disclosure.

Referring to FIG. 2, each sub-pixel SP includes a light-emitting element D connected to a high-potential voltage line supplying a high potential driving voltage (a first driving voltage) EVDD and a low potential voltage line supplying a low-potential driving voltage (a second driving voltage) EVSS; and a pixel circuit including at least a first switching thin-film transistor ST1, a second switching thin-film transistor ST2, a driving thin-film transistor DT and a storage capacitor Cst in order to independently drive the light-emitting element D. The equivalent circuit diagram as shown in FIG. 2 is illustrative, and the number of switching transistors may be changed according to a design of an internal compensation circuit for compensating for a difference between operation characteristics of the sub-pixels SP. The pixel circuit may have various configurations such as 3T1C (3 thin-film transistors, 1 capacitor), 4T1C (4 thin-film transistors, 1 capacitor), 5T1C (5 thin-film transistors, 1 capacitor), 6T1C (6 thin-film transistors, 1 capacitors), 7T1C (7 thin-film transistors, 1 capacitor), etc.

The light-emitting element D includes an anode connected to a source node N2 of the driving thin-film transistor DT, a cathode connected to the low potential voltage line PL2, and an organic light-emissive layer disposed between the anode and the cathode. The anode may be individually disposed in each sub-pixel SP, while the cathode may be a common electrode shared by all sub-pixels SP.

The first switching thin-film transistor ST1 operates based on a scan pulse SCn supplied from the gate driver GIP to one gate line GL1, and supplies a data voltage Vdata supplied from the data driver D-IC to the data line DL to a gate node Ni of the driving thin-film transistor DT.

The second switching thin-film transistor ST2 operates based on a sense pulse SEn supplied from the gate driver DIP to another gate line GL2, and supplies a reference voltage Vref supplied from the data driver D-IC to a reference line RL to the source node N2 of the driving thin-film transistor DT. In one example, in a sensing mode, the second switching thin-film transistor ST2 may provide a current based on the characteristics of the driving thin-film transistor DT or the characteristics of the light-emitting element D to the reference line RL.

The storage capacitor Cst connected to and disposed between the gate node Ni and the source node N2 of the driving thin-film transistor DT charges therein a difference between the data voltage Vdata supplied to the gate node Ni via the first switching thin-film transistor ST1 and the reference voltage Vref supplied to the source node N2 via the second switching thin-film transistor ST2, as a driving voltage Vgs of the driving thin-film transistor DT. The storage capacitor Cst maintains the charged driving voltage Vgs during a light emission period during which the first and second switching thin-film transistors ST1 and ST2 are turned off.

The driving thin-film transistor DT controls current supplied from the high-potential voltage line PL1 based on the driving voltage Vgs supplied from the storage capacitor Cst, and supplies driving current determined based on the driving voltage Vgs to the light-emitting element D such that the light-emitting element D emits light.

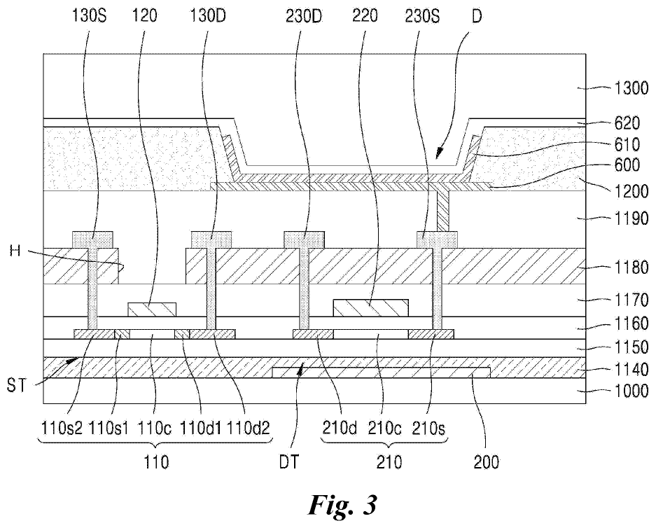

FIG. 3 is a schematic cross-sectional view showing one sub-pixel in a display apparatus according to an embodiment of the present disclosure.

Referring to FIG. 3, one sub-pixel in a display apparatus according to an embodiment of the present disclosure may include a switching thin-film transistor ST, the driving thin-film transistor DT, and the light-emitting element D. The switching thin-film transistor ST may include a first oxide semiconductor layer 110, a first gate electrode 120, a first source electrode 130S, and a first drain electrode 130D. The driving thin-film transistor DT may include a second oxide semiconductor layer 210, a second gate electrode 220, a second source electrode 230S, and a second drain electrode 230D. The light-emitting element D may include an anode 600, an organic light-emissive layer 610 and a cathode 620.

A light-blocking layer 200 may be disposed on a substrate 1000. The light-blocking layer 200 may be disposed at a position where the second oxide semiconductor layer 210 of the driving thin-film transistor DT is to be formed. A size of the light-blocking layer 200 is controlled such that the second oxide semiconductor layer 210 may be entirely covered with the light-blocking layer 200. Preferably, the size of the light-blocking layer 200 may be larger than that of the second oxide semiconductor layer 210. The light-blocking layer 200 may prevent light from a position under the substrate 1000 from being introduced to the second oxide semiconductor layer 210 to prevent deterioration of characteristics of a channel area 210c of the second oxide semiconductor layer 210. The substrate 1000 may be made of glass or a flexible plastic material. The light-blocking layer 200 may include a metal material such as molybdenum (Mo), titanium (Ti) or molybdenum-titanium (MoTi).

A first buffer layer 1140 covering the light-blocking layer 200 may be disposed on the substrate 1000. A second buffer layer 1150 covering the first buffer layer 1140 may be disposed thereon. Each of the first buffer layer 1140 and the second buffer layer 1150 may be embodied as, for example, a single layer made of a silicon oxide, a silicon nitride, or a silicon oxynitride, or a stack of multiple layers made of a silicon oxide, a silicon nitride, and/or a silicon oxynitride. However, the present disclosure is not limited thereto. The first and second buffer layers 1140 and 1150 may block moisture or impurities introduced through the substrate 1000. The first and second buffer layers 1140 and 1150 may be disposed over an entirety of the display area AA on the substrate 1000.

The first oxide semiconductor layer 110 of the switching thin-film transistor ST and the second oxide semiconductor layer 210 of the driving thin-film transistor DT may be disposed on the second buffer layer 1150. The second oxide semiconductor layer 210 of the driving thin-film transistor DT may be disposed at a position overlapping the light-blocking layer 200. A size of the second oxide semiconductor layer 210 may be smaller than that of the light-blocking layer 200.

Each of the first oxide semiconductor layer 110 and the second oxide semiconductor layer 210 may be made of an oxide semiconductor material. For example, each of the first oxide semiconductor layer 110 and the second oxide semiconductor layer 210 may include at least one of IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, and ITZO (InSnZnO)-based oxide semiconductor materials. However, the present disclosure is not limited thereto. Each of the first oxide semiconductor layer 110 and the second oxide semiconductor layer 210 may be made of, for example, an IGZO (InGaZnO)-based oxide semiconductor material.

The first oxide semiconductor layer 110 of the switching thin-film transistor ST may include a first channel area 110c, a first source area 110s2, a first drain area 110d2, a first intermediate source area 110s1, and a first intermediate drain area 110d1.

Each of the first source area 110s2, the first drain area 110d2, the first intermediate source area 110s1, and the first intermediate drain area 110d1 may be an area which is converted to a conductive area via hydrogen treatment. Each of electrical conductivities of the first intermediate source area 110s1 and the first intermediate drain area 110d1 may be lower than each of those of the first source area 110s2 and the first drain area 110d2.

The second oxide semiconductor layer 210 of the driving thin-film transistor DT may include a second channel area 210c, a second source area 210s, and a second drain area 210d. Each of the second source area 210s and the second drain area 210d may be an area which is converted to a conductive area via hydrogen treatment.

A gate insulating film 1160 may be disposed on the first oxide semiconductor layer 110 and the second oxide semiconductor layer 210. The gate insulating film 1160 may be disposed over the entire display area AA on the substrate 1000 while covering the first and second oxide semiconductor layers 110 and 210. The gate insulating film 1160 may be embodied as, for example, a single layer made of a silicon oxide, a silicon nitride, or a silicon oxynitride, or a stack of multiple layers made of a silicon oxide, a silicon nitride, and/or a silicon oxynitride. However, the present disclosure is not limited thereto.

The first gate electrode 120 of the switching thin-film transistor ST and the second gate electrode 220 of the driving thin-film transistor DT may be disposed on the gate insulating film 1160. The first gate electrode 120 may be disposed at a position overlapping the first channel area 110c, and the second gate electrode 220 may be disposed at a position overlapping the second channel area 210c.

The first gate electrode 120 may be insulated from the first oxide semiconductor layer 110 by the gate insulating film 1160, while the second gate electrode 220 may be insulated from the second oxide semiconductor layer 210 by the gate insulating film 1160.

Each of the first gate electrode 120 and the second gate electrode 220 may be embodied as, for example, a single layer made of one of molybdenum (Mo), aluminum (Al), chromium (Cr), gold (Au), titanium (Ti), nickel (Ni), neodymium (Nd) and copper (Cu) or alloys thereof, or a stack of multiple layers made of molybdenum (Mo), aluminum (Al), chromium (Cr), gold (Au), titanium (Ti), nickel (Ni), neodymium (Nd), copper (Cu) and/or alloys thereof. However, the present disclosure is not limited thereto. Each of the first gate electrode 120 and the second gate electrode 220 may be embodied as, for example, a Mo/Ti double layer.

A first interlayer insulating film 1170 may be disposed on the first and second gate electrodes 120 and 220. The first interlayer insulating film 1170 may cover the first and second gate electrodes 120 and 220 and may be disposed over the entire display area AA on the substrate 1000. The first interlayer insulating film 1170 may be embodied as a single layer or a stack of multiple layers made of silicon oxide.

A second interlayer insulating film 1180 may be disposed on the first interlayer insulating film 1170. The second interlayer insulating film 1180 may be embodied as a single layer or a stack of multiple layers made of silicon nitride. The second interlayer insulating film 1180 may have an opening H therein overlapping the first gate electrode 120 and exposing the first interlayer insulating film 1170. A size of the opening H of the second interlayer insulating film 1180 in a channel length direction may be larger than that of the gate electrode 120 in a channel length direction. In this regard, the ‘channel length direction’ means a direction in which the first channel area 110c extends from the first source area 110s2 to the first drain area 110d2, or a opposite direction thereto. The second interlayer insulating film 1180 may be embodied as a single layer or a stack of multiple layers made of silicon nitride, and may contain a large amount of hydrogen. The second interlayer insulating film 1180 may act as a hydrogen source providing hydrogen to the first oxide semiconductor layer 110 and the second oxide semiconductor layer 210.

The first source electrode 130S connected to the first source area 110s2 and the first drain electrode 130D connected to the first drain area 110d2 may be disposed on the second interlayer insulating film 1180. Further, the second source electrode 230S connected to the second source area 210s and the second drain electrode 230D connected to the second drain area 210d may be disposed on the second interlayer insulating film 1180.

The first source electrode 130S and the first drain electrode 130D may extend through the first and second interlayer insulating films 1170 and 1180 so as to be connected to the first source area 110s2 and the first drain area 110d2 respectively. In addition, the second source electrode 230S and the second drain electrode 230D may extend through the first and second interlayer insulating films 1170 and 1180 so as to be connected to the second source area 210s and the second drain area 210d, respectively.

Each of the first source electrode 130S, the first drain electrode 130D, the second source electrode 230S and the second drain electrode 230D may be embodied as, for example, a single layer made of one of molybdenum (Mo), aluminum (Al), chromium (Cr), gold (Au), titanium (Ti), nickel (Ni), neodymium (Nd) and copper (Cu) or alloys thereof, or a stack of multiple layers made of molybdenum (Mo), aluminum (Al), chromium (Cr), gold (Au), titanium (Ti), nickel (Ni), neodymium (Nd), copper (Cu) and/or alloys thereof. However, the present disclosure is not limited thereto. Each of the first source electrode 130S, the first drain electrode 130D, the second source electrode 230S, and the second drain electrode 230D may be embodied as, for example, a Ti/Al/Ti triple layer.

A planarization layer 1190 covering the first source electrode 130S, the first drain electrode 130D, the second source electrode 230S, and the second drain electrode 230D may be disposed on the second interlayer insulating film 1180. The planarization layer 1190 may be made of one or more materials selected from polyacrylates resin, epoxy resin, phenolic resin, polyamides resin, polyimides resin, unsaturated polyesters resin, poly-phenylenethers resin, poly-phenylenesulfides resin, and benzocyclobutene. However, the present disclosure is not limited thereto. The planarization layer 1190 may fill the opening H of the second interlayer insulating film 1180.

A bank layer 1200 and the light-emitting element D may be disposed on the planarization layer 1190. The light-emitting element D may include an anode 600, an organic light-emissive layer 610 and a cathode 620. The anode 600 may be disposed on the planarization layer 1190 and may extend through the planarization layer 1190 so as to be connected to the second source electrode 230S of the driving thin-film transistor DT. The anode 600 may be referred to as a positive electrode, a pixel electrode or a first electrode. The anode 600 may be disposed separately in each sub-pixel of the display area AA.

The anode 600 may include a transparent conductive layer made of a transparent conductive oxide (TCO). The transparent conductive oxide may be, for example, any one of indium tin oxide (ITO), indium zinc oxide (IZO), indium tin zinc oxide (ITZO), zinc oxide, or tin oxide. The anode 151 may further include a reflective layer disposed under the transparent conductive layer. The reflective layer may be made of a metal material having excellent reflectivity, and may be made of, for example, silver (Ag), nickel (Ni), gold (Au), platinum (Pt), aluminum (Al), copper (Cu), or the like.

The bank layer 1200 may be disposed on the anode 600 and the planarization layer 1190. The bank layer 1200 may be disposed between adjacent sub-pixels. Further, the bank layer 1200 may cover an edge of the anode 600. The bank layer 1200 may be made of an organic insulating material. The organic insulating material may include, for example, polyimide, photo acryl, and benzocyclobutene (BCB).

The organic light-emissive layer 610 may be disposed on a portion of the anode 600 not covered with the bank layer 1200 so as to be exposed. An organic light-emissive layer emitting any one of red, green, blue, or white light may be disposed in each sub-pixel. In one embodiment, an organic light-emissive layer emitting white light may be disposed on each of all sub-pixels.

The cathode 620 is disposed on the organic light-emissive layer 610 and the bank layer 1200. The cathode 620 may be referred to as a negative electrode, a common electrode, or a second electrode. The cathode 620 may be embodied as a thin metal material layer having a low work function. For example, when the cathode 620 is made of a metal material having a low work function, the metal material layer made of silver (Ag), titanium (Ti), aluminum (Al), molybdenum (Mo), or an alloy of silver (Ag) and magnesium (Mg) may be formed to have a thickness of tens of nm or smaller, for example to have a thickness of 20 nm or smaller to constitute the cathode 620.

An encapsulation layer 1300 covering the light-emitting element D may be disposed on the light-emitting element D. The encapsulation layer 1300 may protect the thin-film transistors ST and DT, and the light-emitting element D from external moisture, air, impact, and the like. The encapsulation layer 1300 may be disposed over the entire display area AA on the substrate 1000. The encapsulation layer 1300 may include an organic film, an inorganic film, or a combination thereof. The encapsulation layer 1300 may include, for example, a triple layer composed of an inorganic film/an organic film/an inorganic film.

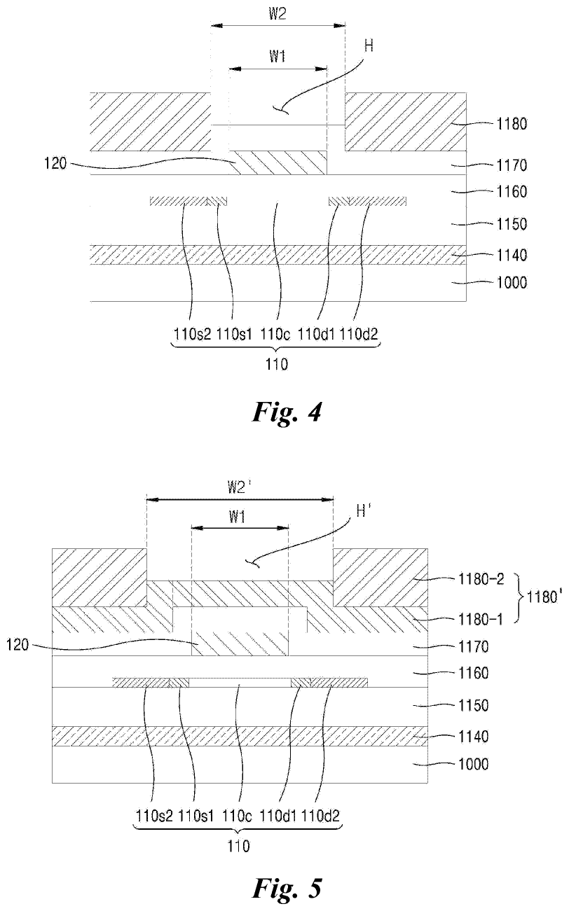

FIG. 4 is a cross-sectional view showing a partial area including the switching thin-film transistor of FIG. 3. In FIG. 4, for convenience of illustration, the planarization layer 1190, the first source electrode 130S, and the first drain electrode 130D are not shown.

Referring to FIG. 4, the first interlayer insulating film 1170 may be disposed on the first gate electrode 120 and the gate insulating film 1160, and the second interlayer insulating film 1180 may be disposed on the first interlayer insulating film 1170. The first interlayer insulating film 1170 may be embodied as a silicon oxide film formed using a chemical vapor deposition (CVD) process, and may be disposed on the gate insulating film 1160 while covering top and side surfaces of the first gate electrode 120. The second interlayer insulating film 1180 may be embodied as, for example, a silicon nitride film formed using a chemical vapor deposition (CVD) process using silane gas and ammonia gas, and may contain a large amount of hydrogen. The second interlayer insulating film 1180 may have the opening H therein overlapping the first gate electrode 120 and exposing the first interlayer insulating film 1170. A size W2 of the opening H of the second interlayer insulating film 1180 in the channel length direction may be greater than a size W1 of the first gate electrode 120 in the channel length direction.

Hydrogen in the second interlayer insulating film 1180 may diffuse into the first oxide semiconductor layer 110 via subsequent heat treatment. Hydrogen implanted into the first oxide semiconductor layer 110 may make the first oxide semiconductor layer 110 conductive. However, in this embodiment, the second interlayer insulating film 1180 as the hydrogen source has the opening H having the size W2 larger than the size W1 of the first gate electrode 120 at a position overlapping the first gate electrode 120. Thus, areas having different hydrogen concentrations, that is, the first channel area 110c, the first source area 110s2, the first drain area 110d2, the first intermediate source area 110s1, and the first intermediate drain area 110d1 may be formed in the first oxide semiconductor layer 110.

Each of the first source area 110s2, the first drain area 110d2, the first intermediate source area 110s1, and the first intermediate drain area 110d1 may be an area which is converted to a conductive area via the hydrogen treatment. The hydrogen concentration of each of the first intermediate source area 110s1 and the first intermediate drain area 110d1 may be lower than that of each of the first source area 110s2 and the first drain area 110d2 and may be higher than that of the first channel area 110c. Therefore, the electrical conductivity of each of the first intermediate source area 110s1 and the first intermediate drain area 110d1 may be lower than that of each of the first source area 110s2 and the first drain area 110d2 and may be higher than that of the first channel area 110c.

A size of each of the first intermediate source area 110s1 and the first intermediate drain area 110d1 may vary based on a difference between the size W2 of the opening H of the second interlayer insulating film 1180 and the size W1 of the first gate electrode 120. As the difference between the size W2 of the opening H of the second interlayer insulating film 1180 and the size W1 of the first gate electrode 120 increases, the size of each of the first intermediate source area 110s1 and the first intermediate drain area 110d1 may increase. Conversely, as the difference between the size W2 of the opening H of the second interlayer insulating film 1180 and the size W1 of the first gate electrode 120 decreases, the size of each of the first intermediate source area 110s1 and the first intermediate drain area 110d1 may decrease. In FIG. 4, it is shown that the difference between the size W2 of the opening H of the second interlayer insulating film 1180 and the size W1 of the first gate electrode 120 is equal to two times of a thickness of the first interlayer insulating film 1170. However, the present disclosure is not limited thereto.

According to an embodiment of the present disclosure, the first oxide semiconductor layer 110 of the switching thin-film transistor ST has the first intermediate source area 110s1 and the first intermediate drain area 110d1 respectively disposed between the first channel area 110c and the first source area 110s2 and between the first channel area 110c and the first drain area 110d2, and having lower electrical conductivity than those of the first source area 110s2 and the first drain area 110d2, respectively. Thus, the short-channel effect of the switching thin-film transistor ST can be reduced or suppressed to secure stable characteristics of the switching thin-film transistor ST.

FIGS. 5 to 7 are respectively cross-sectional views showing modified structures of the partial area including the switching thin-film transistor of FIG. 3 according to embodiments of the present disclosure. In FIGS. 5 to 7, for convenience of illustration, the planarization layer 1190, the first source electrode 130S, and the first drain electrode 130D are not shown.

Referring to FIG. 5, the first interlayer insulating film 1170 may be disposed on the first gate electrode 120 and the gate insulating film 1160. A second lower interlayer insulating film 1180-1 and a second upper interlayer insulating film 1180-2 may be disposed on the first interlayer insulating film 1170. The second lower interlayer insulating film 1180-1 and the second upper interlayer insulating film 1180-2 may constitute a second interlayer insulating film 1180′. The first interlayer insulating film 1170 may be embodied as a silicon oxide film formed using a chemical vapor deposition (CVD) process, and may be disposed on the gate insulating film 1160 while covering the top and side surfaces of the first gate electrode 120. Each of the second lower interlayer insulating film 1180-1 and the second upper interlayer insulating film 1180-2 may be embodied as, for example, a silicon nitride film formed using a chemical vapor deposition (CVD) process using silane gas and ammonia gas, and may contain a large amount of hydrogen. The hydrogen content of the second lower interlayer insulating film 1180-1 may be lower than that of the second upper interlayer insulating film 1180-2. The second upper interlayer insulating film 1180-2 may have an opening H′ therein that overlaps the first gate electrode 120 and exposes the second lower interlayer insulating film 1180-1. A size W2′ of the opening H′ of the second upper interlayer insulating film 1180-2 in the channel length direction may be greater than the size W1 of the first gate electrode 120 in the channel length direction.

Hydrogen in the second lower interlayer insulating film 1180-1 and the second upper interlayer insulating film 1180-2 may diffuse into the first oxide semiconductor layer 110 under subsequent heat treatment. Hydrogen implanted into the first oxide semiconductor layer 110 may make the first oxide semiconductor layer 110 conductive. However, in this embodiment, the second upper interlayer insulating film 1180-2 has the opening H′ therein having the size W2′ larger than the size W1 of the first gate electrode 120 at a position overlapping the first gate electrode 120, and the second lower interlayer insulating film 1180-1 has a lower hydrogen content than that of the second upper interlayer insulating film 1180-2. Thus, areas with different hydrogen concentrations, that is, the first channel area 110c, the first source area 110s2, the first drain area 110d2, the first intermediate source area 110s1, and the first intermediate drain area 110d1 may be formed in the first oxide semiconductor layer 110.

Each of the first source area 110s2, the first drain area 110d2, the first intermediate source area 110s1, and the first intermediate drain area 110d1 may be an area which is converted to a conductive area via hydrogen treatment. The hydrogen concentration of each of the first intermediate source area 110s1 and the first intermediate drain area 110d1 may be lower than that of each of the first source area 110s2 and the first drain area 110d2 and may be higher than that of the first channel area 110c.

The size of each of the first intermediate source area 110s1 and the first intermediate drain area 110d1 may vary according to the difference between the size W2′ of the opening H′ of the second upper interlayer insulating film 1180-2 and the size W1 of the first gate electrode 120. As the difference between the size W2′ of the opening H′ of the second upper interlayer insulating film 1180-2 and the size W1 of the first gate electrode 120 increases, the size of each of the first intermediate source area 110s1 and the first intermediate drain area 110d1 may increase. Conversely, as the difference between the size W2′ of opening H′ of the second upper interlayer insulating film 1180-2 and the size W1 of the first gate electrode 120 decreases, the size of each of the first intermediate source area 110s1 and the first intermediate drain area 110d1 may decrease.

According to an embodiment of the present disclosure, the first oxide semiconductor layer 110 of the switching thin-film transistor ST has the first intermediate source area 110s1 and the first intermediate drain area 110d1 respectively disposed between the first channel area 110c and the first source area 110s2 and between the first channel area 110c and the first drain area 110d2, and having lower electrical conductivity than those of the first source area 110s2 and the first drain area 110d2, respectively. Thus, the short-channel effect of the switching thin-film transistor ST can be reduced or suppressed to secure stable characteristics of the switching thin-film transistor ST.

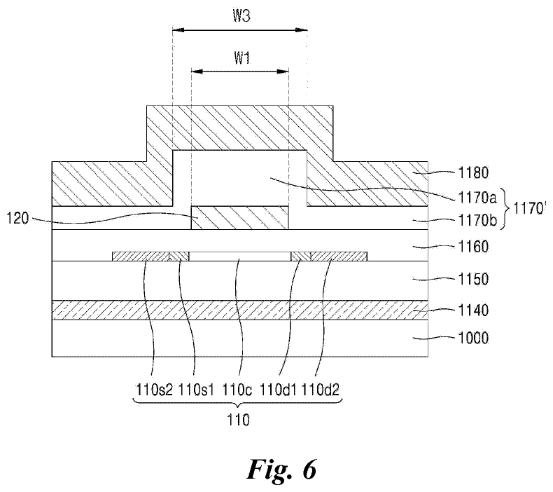

Referring to FIG. 6, a first interlayer insulating film 1170′ may be disposed on the first gate electrode 120 and the gate insulating film 1160. The second interlayer insulating film 1180 may be disposed on the first interlayer insulating film 1170′. The first interlayer insulating film 1170′ may include a first portion 1170a on the first gate electrode 120 and a second portion 1170b on the gate insulating film 1160. A thickness of the first portion 1170a of the first interlayer insulating film 1170′ may be greater than a thickness of the second portion 1170b of the first interlayer insulating film 1170′. A size W3 of the first portion 1170a of the first interlayer insulating film 1170′ in the channel length direction may be greater than the size W1 of the first gate electrode 120 in the channel length direction. The second interlayer insulating film 1180 may cover the first portion 1170a and the second portion 1170b of the first interlayer insulating film 1170′.

The first interlayer insulating film 1170′ may be embodied as a silicon oxide film formed using a chemical vapor deposition (CVD) process and may be disposed on the gate insulating film 1160 while covering the top and side surfaces of the first gate electrode 120. The second interlayer insulating film 1180 may be embodied as of, for example, a silicon nitride film formed using a chemical vapor deposition (CVD) process using silane gas and ammonia gas, and may contain a large amount of hydrogen.

Hydrogen in the second interlayer insulating film 1180 may diffuse into the first oxide semiconductor layer 110 under subsequent heat treatment. Hydrogen implanted into the first oxide semiconductor layer 110 may make the first oxide semiconductor layer 110 conductive. However, in this embodiment, the first interlayer insulating film 1170′ has the first portion 1170a having the size W3 larger than the size W1 of the first gate electrode 120 and thicker than the second portion 1170b and disposed at a position overlapping the first gate electrode 120. Thus, areas with different hydrogen concentrations, that is, the first channel area 110c, the first source area 110s2, the first drain area 110d2, the first intermediate source area 110s1, and the first intermediate drain area 110d1 may be formed in the first oxide semiconductor layer 110.

Each of the first source area 110s2, the first drain area 110d2, the first intermediate source area 110s1, and the first intermediate drain area 110d1 may be an area which is converted to a conductive area via hydrogen treatment. The hydrogen concentration of each of the first intermediate source area 110s1 and the first intermediate drain area 110d1 may be lower than that of each of the first source area 110s2 and the first drain area 110d2 and may be higher than that of the first channel area 110c.

The size of each of the first intermediate source area 110s1 and the first intermediate drain area 110d1 may vary according to a difference between the size W3 of the first portion 1170a of the first interlayer insulating film 1170′ and the size W1 of the first gate electrode 120. As the difference between the size W3 of the first portion 1170a of the first interlayer insulating film 1170′ and the size W1 of the first gate electrode 120 increases, the size of each of the first intermediate source area 110s1 and the first intermediate drain area 110d1 may increase. Conversely, as the difference between the size W3 of the first portion 1170a of the first interlayer insulating film 1170′ and the size W1 of the first gate electrode 120 decreases, the size of each of the first intermediate source area 110s1 and the first intermediate drain area 110d1 may decrease.

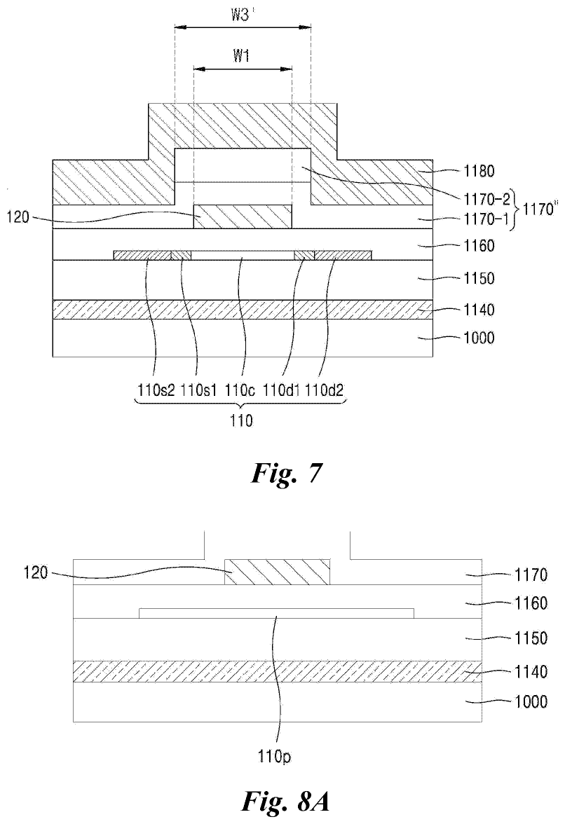

Referring to FIG. 7, a structure thereof is similar to that of FIG. 6, whereas there is a difference therebetween in that a first interlayer insulating film 1170″ in FIG. 7 includes a first lower interlayer insulating layer 1170-1 and a first upper interlayer insulating layer 1170-2. Following description is based on the differences thereof from the structure of FIG. 6. The first interlayer insulating film 1170″ may be disposed on the first gate electrode 120, and the second interlayer insulating film 1180 may be disposed on the first interlayer insulating film 1170″. The second interlayer insulating film 1180 may cover first lower interlayer insulating layer 1170-1 and the first upper interlayer insulating layer 1170-2. The first interlayer insulating film 1170″ may include the first lower interlayer insulating layer 1170-1 disposed on the first gate electrode 120 and gate insulating film 1160 or covering the first gate electrode 120 and gate insulating film 1160, and the first upper interlayer insulating layer 1170-2 disposed on the first lower interlayer insulating layer 1170-1 and at a position overlapping the first gate electrode 120. A size W3′ of the first upper interlayer insulating layer 1170-2 in the channel length direction may be greater than the size W1 of the first gate electrode 120 in the channel length direction.

In this embodiment, the first interlayer insulating film 1170″ further has the first upper interlayer insulating layer 1170-2 disposed on the first lower interlayer insulating layer 1170-1 and at a position overlapping the first gate electrode 120. Thus, areas with different hydrogen concentrations, that is, the first channel area 110c, the first source area 110s2, the first drain area 110d2, the first intermediate source area 110s1, and the first intermediate drain area 110d1 may be formed in the first oxide semiconductor layer 110.

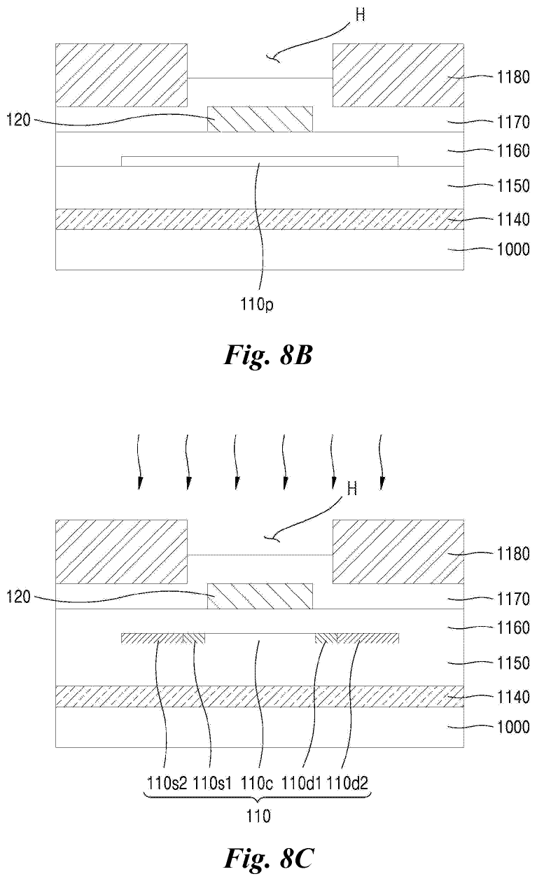

FIG. 8A to FIG. 8C are cross-sectional views showing a manufacturing process of the switching thin-film transistor as shown in FIG. 4.

Referring to FIG. 8A, the first buffer layer 1140 and the second buffer layer 1150 are formed on the substrate 1000, and then a first pre-oxide semiconductor layer 110p is formed on the second buffer layer 1150. The first pre-oxide semiconductor layer 110p may be made of an oxide semiconductor material. The first pre-oxide semiconductor layer 110p may include at least one of IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, and ITZO (InSnZnO)-based oxide semiconductor materials. However, the present disclosure is not limited thereto. The first pre-oxide semiconductor layer 110p may be made of, for example, an IGZO (InGaZnO)-based oxide semiconductor material. However, the present disclosure is not limited thereto.

Then, the gate insulating film 1160 is formed on the first pre-oxide semiconductor layer 110p. Then, the first gate electrode 120 is formed on the gate insulating film 1160 and at a position overlapping the first pre-oxide semiconductor layer 110p.

Then, the first interlayer insulating film 1170 covering the first gate electrode 120 is formed on the gate insulating film 1160. The first interlayer insulating film 1170 may be formed using, for example, a chemical vapor deposition process using silane and oxygen gas.

Referring to FIG. 8B, then, the second interlayer insulating film 1180 covering the first interlayer insulating film 1170 is formed. The second interlayer insulating film 1180 may be embodied as, for example, a silicon nitride film formed using a chemical vapor deposition process using silane gas and ammonia gas. The second interlayer insulating film 1180 may contain a large amount of hydrogen.

Then, the opening H having the size larger than the size of the first gate electrode 120 is formed at a position overlapping the first gate electrode 120 and in the second interlayer insulating film 1180 as the hydrogen source, using, for example, a photolithography process and an etching process. The size of the opening H of the second interlayer insulating film 1180 may be adjusted according to the size of each of the first intermediate source area 110s1 and the first intermediate drain area 110d1 to be formed.

Referring to FIG. 8C, then, heat treatment is performed at a temperature ranging from 350° C. to 400° C. for 10 minutes to 20 minutes, for example, at 372° C. for 15 minutes in a nitrogen atmosphere.

Hydrogen in the second interlayer insulating film 1180 is implanted into the first pre-oxide semiconductor layer 110p via the heat treatment. Edge areas of the first pre-oxide semiconductor layer 110p into which the hydrogen is implanted may be converted into conductive areas such that the first source area 110s2, the first drain area 110d2, the first intermediate source area 110s1, and the first intermediate drain area 110d1 are formed. Hydrogen is not injected into a central area of the first pre-oxide semiconductor layer 110p overlapping the first gate electrode 120 or a small amount of the hydrogen is injected thereto, such that the channel area 110c in which semiconductor characteristics are maintained may be formed. The hydrogen concentration of each of the first intermediate source area 110s1 and the first intermediate drain area 110d1 may be lower than that of each of the first source area 110s2 and the first drain area 110d2 and may be higher than that of the first channel area 110c.

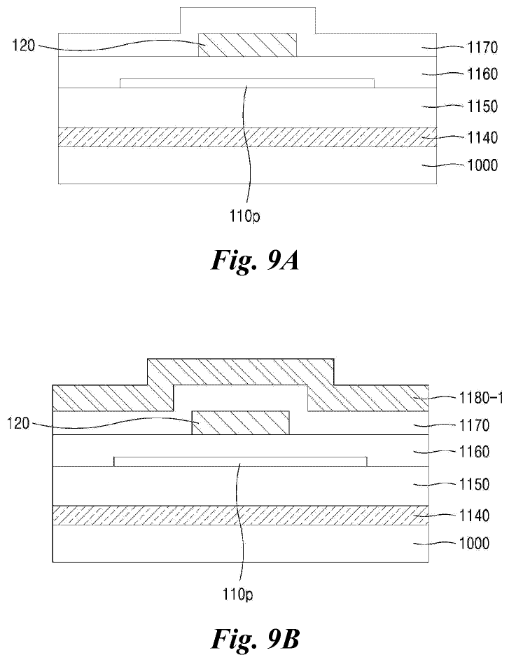

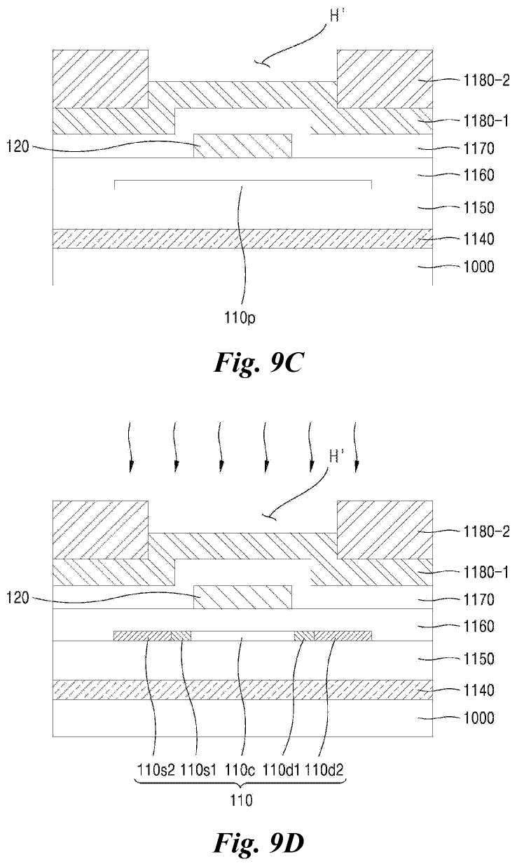

FIG. 9A to FIG. 9D are cross-sectional views showing a manufacturing process of the switching thin-film transistor as shown in FIG. 5.

Referring to FIG. 9A, as described with reference to FIG. 8A, the first buffer layer 1140, the second buffer layer 1150, the first pre-oxide semiconductor layer 110p, the gate insulating film 1160, the first gate electrode 120 and the first interlayer insulating film 1170 may be formed on the substrate 1000.

Referring to FIG. 9B, then, the second lower interlayer insulating film 1180-1 may be formed on the first interlayer insulating film 1170. The second lower interlayer insulating film 1180-1 may be embodied as, for example, a silicon nitride film formed using a chemical vapor deposition process using silane gas and ammonia gas.

Referring to FIG. 9C, then, the second upper interlayer insulating film 1180-2 may be formed on the second lower interlayer insulating film 1180-1. The second upper interlayer insulating film 1180-2 may be embodied as, for example, a silicon nitride film formed using a chemical vapor deposition process using silane gas and ammonia gas. A hydrogen content in the second upper interlayer insulating film 1180-2 may be greater than a hydrogen content in the second lower interlayer insulating film 1180-1. The hydrogen content in the silicon nitride film may vary depending on a mixing ratio of silane gas and ammonia gas.

Then, the opening H′ having the size larger than the size of the first gate electrode 120 is formed at a position overlapping the first gate electrode 120 and in the second upper interlayer insulating film 1180-2 using, for example, a photolithography process and an etching process. The size of the opening H′ of the second upper interlayer insulating film 1180-2 may be adjusted according to the size of each of the first intermediate source area 110s1 and the first intermediate drain area 110d1 to be formed. In the etching process, the second lower interlayer insulating film 1180-1 may be partially etched.

Referring to FIG. 9D, then, heat treatment is performed at a temperature ranging from 350° C. to 400° C. for 10 minutes to 20 minutes, for example, at 372° C. for 15 minutes in a nitrogen atmosphere.

Hydrogen in the second interlayer insulating film 1180 is injected into the edge areas of the first pre-oxide semiconductor layer 110p via the heat treatment, so that the first source area 110s2, the first drain area 110d2, the first intermediate source area 110s1, and the first intermediate drain area 110d1 may be formed. Hydrogen is not injected into a central area of the first pre-oxide semiconductor layer 110p overlapping the first gate electrode 120 or a small amount of the hydrogen is injected thereto, such that the channel area 110c in which semiconductor characteristics are maintained may be formed.

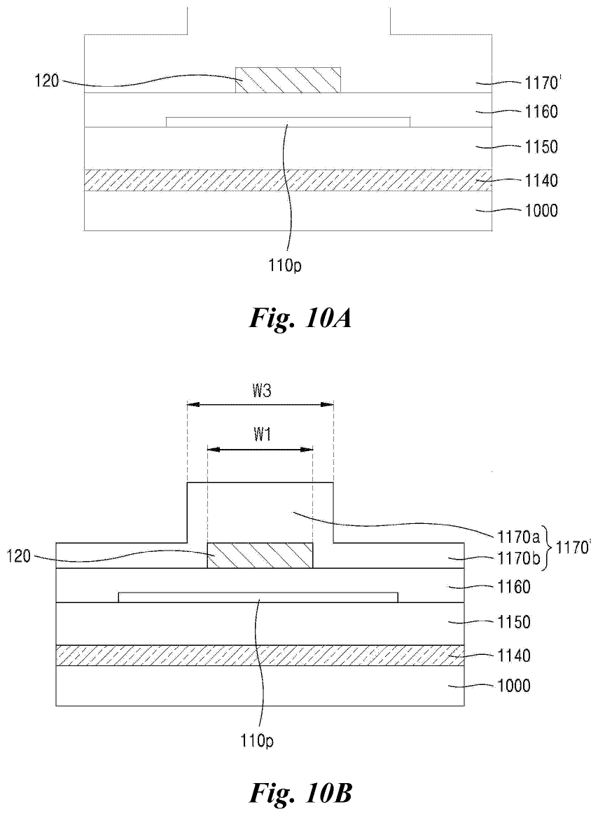

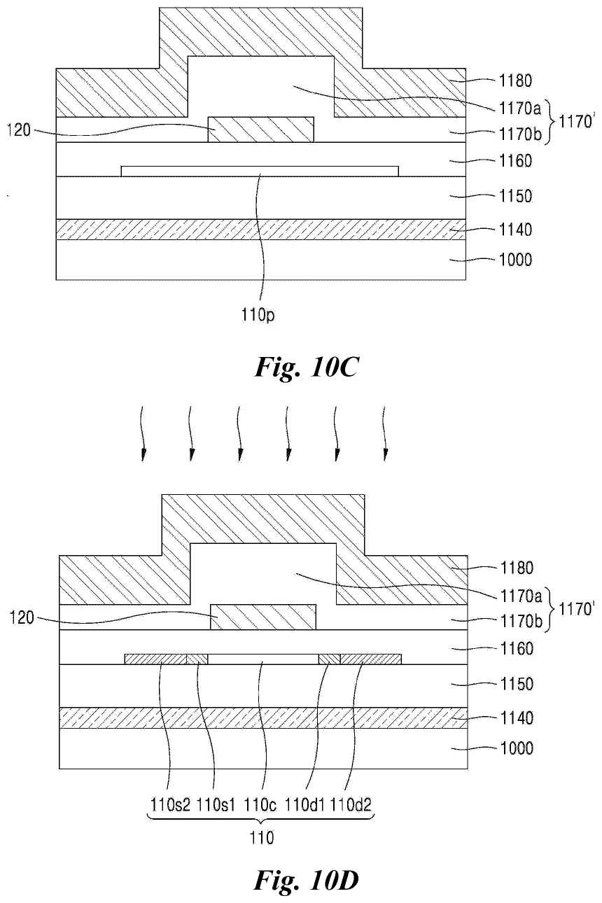

FIG. 10A to FIG. 10D are cross-sectional views showing a manufacturing process of the switching thin-film transistor as shown in FIG. 6.

Referring to FIG. 10A, as described with reference to FIG. 8A, the first buffer layer 1140, the second buffer layer 1150, the first pre-oxide semiconductor layer 110p, the gate insulating film 1160, the first gate electrode 120 and the first interlayer insulating film 1170′ may be formed on the substrate 1000. In this regard, the first interlayer insulating film 1170′ may be formed to be thicker than the first interlayer insulating film 1170 of the structure as shown in FIG. 8A.

Referring to FIG. 10B, a portion of the first interlayer insulating film 1170′ that does not overlap with the first gate electrode 120 may be removed using, for example, a photolithography process and an etching process. Accordingly, the first interlayer insulating film 1170′ may include the first portion 1170a overlapping the first gate electrode 120 and the second portion 1170b disposed on the gate insulating film 1160 and non-overlapping the first gate electrode 120. A thickness of the first portion 1170a may be greater than a thickness of the second portion 1170b. The size W3 of the first portion 1170a may be greater than the size W1 of the first gate electrode 120.

Referring to FIG. 10C, then, the second interlayer insulating film 1180 may be formed on the first interlayer insulating film 1170′. The second interlayer insulating film 1180 may be embodied as, for example, a silicon nitride film formed using a chemical vapor deposition process using silane gas and ammonia gas.

Referring to FIG. 10D, then, heat treatment is performed at a temperature ranging from 350° C. to 400° C. for 10 minutes to 20 minutes, for example, at 372° C. for 15 minutes in a nitrogen atmosphere.

Hydrogen in the second interlayer insulating film 1180 is implanted into edge areas of the first pre-oxide semiconductor layer 110p via the heat treatment, such that the first source area 110s2, the first drain area 110d2, the first intermediate source area 110s1, and the first intermediate drain area 110d1 may be formed. Hydrogen is not injected into a central area of the first pre-oxide semiconductor layer 110p overlapping the first gate electrode 120 or a small amount of the hydrogen is injected thereto, such that the channel area 110c in which semiconductor characteristics are maintained may be formed.

A manufacturing process of the switching thin-film transistor as shown in FIG. 7 is similar to the manufacturing process of the switching thin-film transistor as shown in FIG. 6 as described above with reference to FIGS. 10A to 10D. In the manufacturing process of the switching thin-film transistor as shown in FIG. 7, instead of forming the first interlayer insulating film 1170′ thicker than the first interlayer insulating film 1170 of the structure as shown in FIG. 8A, the first lower interlayer insulating layer 1170-1 and the first upper interlayer insulating layer 1170-2 may be separately formed in FIG. 10A. Then, the processes as described above with reference to FIGS. 10B to 10D may be performed.

One switching thin-film transistor included in the sub-pixel has been described above. However, in other embodiments, the above descriptions may be equally applied to each of some or all of the oxide semiconductor thin-film transistors included in the sub-pixel.

A display apparatus according to the embodiments of the present disclosure may be described as follows.

A first aspect of the present disclosure provides a display apparatus comprising: a substrate; an oxide semiconductor layer disposed on the substrate; a gate insulating film disposed on the oxide semiconductor layer; a gate electrode disposed on the gate insulating film; a first interlayer insulating film disposed on the gate insulating film and the gate electrode; a second interlayer insulating film disposed on the first interlayer insulating film; a source electrode connected to the oxide semiconductor layer; and a drain electrode spaced apart from the source electrode and connected to the oxide semiconductor layer, wherein the oxide semiconductor layer includes: a channel area overlapping the gate electrode; a source area connected to the source electrode; a drain area connected to the drain electrode; an intermediate source area disposed between the channel area and the source area; and an intermediate drain area disposed between the channel area and the drain area, wherein a hydrogen concentration of each of the intermediate source area and the intermediate drain area is lower than a hydrogen concentration of each of the source area and the drain area.

In some implementations of the first aspect, the second interlayer insulating film is made of a silicon nitride film, wherein the second interlayer insulating film has an opening therein overlapping the gate electrode so as to expose the first interlayer insulating film, wherein a size of the opening in a channel length direction is greater than a size of the gate electrode in the channel length direction.

In some implementations of the first aspect, the second interlayer insulating film includes a second lower interlayer insulating film disposed on the first interlayer insulating film, and a second upper interlayer insulating film disposed on the second lower interlayer insulating film, wherein the second upper interlayer insulating film has an opening therein overlapping the gate electrode so as to expose the second lower interlayer insulating film, wherein a size of the opening in a channel length direction is greater than a size of the gate electrode in the channel length direction.

In some implementations of the first aspect, each of the second lower interlayer insulating film and the second upper interlayer insulating film is made of a silicon nitride film, wherein a hydrogen concentration of the second lower interlayer insulating film is lower than a hydrogen concentration of the second upper interlayer insulating film.

In some implementations of the first aspect, the first interlayer insulating film is made of silicon oxide, wherein the first interlayer insulating film includes a first portion disposed on the gate electrode, and a second portion disposed on the gate insulating film, wherein a thickness of the first portion is larger than a thickness of the second portion.

In some implementations of the first aspect, a size of the first portion in a channel length direction is greater than a size of the gate electrode in the channel length direction.

In some implementations of the first aspect, the second interlayer insulating film is made of silicon nitride, wherein the second interlayer insulating film covers the first portion and the second portion of the first interlayer insulating film.

In some implementations of the first aspect, the first interlayer insulating film includes: a first lower interlayer insulating film covering the gate electrode and the gate insulating film; and a first upper interlayer insulating film overlapping the gate electrode and disposed on the first lower interlayer insulating film, wherein each of the first lower interlayer insulating film and the first upper interlayer insulating film is made of silicon oxide.

In some implementations of the first aspect, a size of the first upper interlayer insulating film in a channel length direction is greater than a size of the gate electrode in the channel length direction.

In some implementations of the first aspect, the second interlayer insulating film is made of silicon nitride, wherein the second interlayer insulating film covers the first lower interlayer insulating film and the first upper interlayer insulating film.

A second aspect of the present disclosure provides a display apparatus comprising: a substrate; an oxide semiconductor layer disposed on the substrate; a gate insulating film disposed on the oxide semiconductor layer; a gate electrode disposed on the gate insulating film; a silicon oxide film disposed on the gate insulating film and the gate electrode; and a silicon nitride film disposed on the silicon oxide film, wherein the oxide semiconductor layer includes: a source area; a drain area; an intermediate source area having a hydrogen concentration lower than a hydrogen concentration of the source area; and an intermediate drain area having a hydrogen concentration lower than a hydrogen concentration of the drain area.

In some implementations of the second aspect, the silicon oxide film has one portion overlapping the gate electrode, and the other portion non-overlapping the gate electrode, wherein a thickness of the one portion is larger than a thickness of the other portion.

In some implementations of the second aspect, the silicon nitride film has one portion overlapping the gate electrode, and the other portion non-overlapping the gate electrode, wherein a thickness of the one portion is smaller than a thickness of the other portion; or wherein the silicon nitride film has an opening therein overlapping the gate electrode so as to expose the silicon oxide film.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate;
an oxide semiconductor layer disposed on the substrate;
a gate insulating film disposed on the oxide semiconductor layer;
a gate electrode disposed on the gate insulating film;
a first interlayer insulating film disposed on the gate insulating film and the gate electrode;
a second interlayer insulating film disposed on the first interlayer insulating film;
a source electrode connected to the oxide semiconductor layer; and
a drain electrode spaced apart from the source electrode and connected to the oxide semiconductor layer,
wherein the oxide semiconductor layer includes:
a channel area overlapping the gate electrode;
a source area connected to the source electrode;
a drain area connected to the drain electrode;
an intermediate source area disposed between the channel area and the source area; and
an intermediate drain area disposed between the channel area and the drain area,
wherein a hydrogen concentration of each of the intermediate source area and the intermediate drain area is lower than a hydrogen concentration of each of the source area and the drain area.

2. The display apparatus of claim 1, wherein the second interlayer insulating film includes a silicon nitride film,
wherein the second interlayer insulating film has an opening therein overlapping the gate electrode so as to expose the first interlayer insulating film,
wherein a size of the opening in a channel length direction is greater than a size of the gate electrode in the channel length direction.

3. The display apparatus of claim 1, wherein the second interlayer insulating film includes a second lower interlayer insulating film disposed on the first interlayer insulating film, and a second upper interlayer insulating film disposed on the second lower interlayer insulating film,
wherein the second upper interlayer insulating film has an opening therein overlapping the gate electrode so as to expose the second lower interlayer insulating film,
wherein a size of the opening in a channel length direction is greater than a size of the gate electrode in the channel length direction.

4. The display apparatus of claim 3, wherein each of the second lower interlayer insulating film and the second upper interlayer insulating film includes a silicon nitride film,
wherein a hydrogen concentration of the second lower interlayer insulating film is lower than a hydrogen concentration of the second upper interlayer insulating film.

5. The display apparatus of claim 1, wherein the first interlayer insulating film includes silicon oxide,
wherein the first interlayer insulating film includes a first portion disposed on the gate electrode and a second portion disposed on the gate insulating film,
wherein a thickness of the first portion is larger than a thickness of the second portion.

6. The display apparatus of claim 5, wherein a size of the first portion in a channel length direction is greater than a size of the gate electrode in the channel length direction.

7. The display apparatus of claim 5, wherein the second interlayer insulating film includes silicon nitride,
wherein the second interlayer insulating film covers the first portion and the second portion of the first interlayer insulating film.

8. The display apparatus of claim 1, wherein the first interlayer insulating film includes:
a first lower interlayer insulating film covering the gate electrode and the gate insulating film; and
a first upper interlayer insulating film overlapping the gate electrode and disposed on the first lower interlayer insulating film,
wherein each of the first lower interlayer insulating film and the first upper interlayer insulating film includes silicon oxide.

9. The display apparatus of claim 8, wherein a size of the first upper interlayer insulating film in a channel length direction is greater than a size of the gate electrode in the channel length direction.

10. The display apparatus of claim 8, wherein the second interlayer insulating film includes silicon nitride,
wherein the second interlayer insulating film covers the first lower interlayer insulating film and the first upper interlayer insulating film.

11. The display apparatus of claim 1, wherein the second interlayer insulating film acts as a hydrogen source providing hydrogen to the oxide semiconductor layer.

12. A display apparatus comprising:
a substrate;
an oxide semiconductor layer disposed on the substrate;
a gate insulating film disposed on the oxide semiconductor layer;
a gate electrode disposed on the gate insulating film;
a silicon oxide film disposed on the gate insulating film and the gate electrode; and
a silicon nitride film disposed on the silicon oxide film,
wherein the oxide semiconductor layer includes:
a source area;
a drain area;
an intermediate source area having a hydrogen concentration lower than a hydrogen concentration of the source area; and
an intermediate drain area having a hydrogen concentration lower than a hydrogen concentration of the drain area.

13. The display apparatus of claim 12, wherein the silicon oxide film has one portion overlapping the gate electrode and another portion that does not overlap the gate electrode, wherein a thickness of the one portion is larger than a thickness of the another portion.

14. The display apparatus of claim 12, wherein the silicon nitride film has one portion overlapping the gate electrode and another portion that does not overlap the gate electrode, wherein a thickness of the one portion is smaller than a thickness of the another portion; or
wherein the silicon nitride film has an opening therein overlapping the gate electrode so as to expose the silicon oxide film.

15. The display apparatus of claim 12, wherein the silicon nitride film acts as a hydrogen source providing hydrogen to the oxide semiconductor layer.
